(19) United States
(12) Patent Application Publication
(10) Pub. No.: US 2026/0005159 A1
(43) Pub. Date: Jan. 1, 2026

(54) RECONSTITUTED GLASS PANEL FOR HYBRID PANEL MANUFACTURING

(71) Applicant: Intel Corporation, Santa Clara, CA (US)

(72) Inventors: Yekan WANG, Chandler, AZ (US); Andrew JIMENEZ, Mesa, AZ (US); Zhixin XIE, Chandler, AZ (US); Manohar KONCHADY, Chandler, AZ (US); Srinivas Venkata Ramanuja PIETAMBARAM, Chandler, AZ (US); Nirupama CHAKRAPANI, Chandler, AZ (US); Jung Kyu HAN, Chandler, AZ (US); Gang DUAN, Chandler, AZ (US)

(21) Appl. No.: 18/758,203

(22) Filed: Jun. 28, 2024

(51) Int. Cl. H01L 23/00; H01L 23/15

(52) U.S. Cl. CPC H01L 23/562; H01L 23/15

(57) ABSTRACT

Embodiments disclosed herein include an apparatus that comprises a first layer with a first surface, a second surface, and a sidewall surface that couples the first surface to the second surface. In an embodiment, the first layer comprises a glass layer. In an embodiment, a second layer is on the first surface, the second surface, and the sidewall surface of the first layer. In an embodiment, the second layer is an organic dielectric material. In an embodiment, a third layer is on the second layer, and the third layer is a metallic material. In an embodiment, an edge of the third layer is substantially coplanar with an edge of the second layer.

### BACKGROUND

Electronics packaging substrates often include a core. Existing core materials include organic dielectrics that may include fiber reinforcement materials. As devices continue to become more complex, better performing core materials are desired. A package cores that includes a solid glass layer is one potential option. Glass cores enable stiffer substrates, flatter surfaces, and can improve electrical performance.

However, the fragile nature of glass makes full-size glass panel edges extremely vulnerable to damage due to frequent contact of the edges during handling and processing. Designated toolsets that can handle and process glass panels need to be specially designed, and they are not widely available in the industry. This leads to a high technology improvement cost in order to enable a switch from organic core processing to glass core processing in a high volume manufacturing (HVM) environment.

### BRIEF DESCRIPTION OF THE DRAWINGS

FIG. 1A is a plan view illustration of a hybrid panel with a glass substrate and a frame around the glass substrate, in accordance with an embodiment.

FIGS. 1B-1E are cross-sectional illustrations that depict a process for assembling a hybrid panel with a glass substrate and an organic frame, in accordance with an embodiment.

FIGS. 2A and 2B are cross-sectional illustrations of hybrid panels in accordance with additional embodiments.

FIG. 3 is a flow diagram of a process for forming a hybrid panel with a glass substrate and an organic frame, in accordance with an embodiment.

FIGS. 4A-4F are cross-sectional illustrations that depict a process for assembling a hybrid panel with a glass substrate and an organic frame, in accordance with an embodiment.

FIG. 5 is a flow diagram of a process for forming a hybrid panel with a glass substrate and an organic frame with trimmed edges, in accordance with an embodiment.

FIG. 6A is a cross-sectional illustration of a reconstituted panel that is held by a frame, where a plurality of glass units are within the frame, in accordance with an embodiment.

FIG. 6B is a cross-sectional illustration of a reconstituted panel that is held by a frame, where quarter panel units are within the frame, in accordance with an embodiment.

FIG. 6C is a cross-sectional illustration of a reconstituted panel that is held by a frame, where a panel level glass substrate is within the frame, in accordance with an embodiment.

FIGS. 7A-7E are cross-sectional illustrations that depict a process for forming a unit from a hybrid frame, in accordance with an embodiment.

FIGS. 8A-8C are cross-sectional illustrations that depict a process for forming a unit from a hybrid frame, in accordance with an embodiment.

FIG. 9 is a flow diagram of a process for forming a unit device from a hybrid frame, in accordance with an embodiment.

FIG. 10 is a cross-sectional illustration of a package substrate that is singulated from a hybrid frame, in accordance with an embodiment.

FIG. 11 is a cross-sectional illustration of an electronic system with a package substrate that comprises a glass core, in accordance with an embodiment.

FIG. 12 is a schematic of a computing device built in accordance with an embodiment.

### EMBODIMENTS OF THE PRESENT DISCLOSURE

Described herein are reconstituted panels with a glass substrate surrounded by a dielectric frame, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, package substrates that include glass cores have the potential to improve some manufacturing processes and enable higher performing devices compared to existing organic core solutions. However, glass substrates are fragile. For example, contact to the edge of the glass substrate can lead to chipping, cracking, and/or the like. The development of new processing tools is one option for handling glass core substrates, but such an approach would be expensive.

Accordingly, embodiments disclosed herein include the use of hybrid panels. In a hybrid panel, a glass substrate is surrounded by a frame that comprises an organic substrate. The glass substrate and the frame may be molded to each other (e.g., with a buildup film or the like). Since the outer edge of the hybrid panel is an organic substrate, existing manufacturing tools can be used to process the hybrid panel, and the fragile glass substrate is protected. In some embodiments, the glass panel may be a slightly smaller panel (SSP), and the frame may have an outer perimeter that is panel sized and an inner perimeter that accommodates the SSP.

In some embodiments, the stress at the molded joint between the frame and the glass panel may be relatively high at certain points of processing. In order to prevent damage at the joint, embodiments described herein may also comprise one or more reinforcement strips that are provided across a gap between an outer edge of the glass substrate and an inner edge of the frame. The reinforcement strips may include a glass cloth prepreg material, a metallic material (e.g., copper), or the like.

In another embodiment, the frame may be oversized so that an outer perimeter of the frame is larger than a standard panel form factor. After the reinforcement strips are applied over the frame and the glass substrate, the frame may be trimmed to have a panel form factor. In such an embodiment, the outer edges of the reinforcement strips may be substantially coplanar with the outer edges of the frame.

In yet another embodiment, a reconstituted glass panel solution may be provided. In such an embodiment, the reconstituted glass panel may include a plurality of glass cores that are overmolded within an organic frame. The plurality of glass cores may be processed as a larger panel to provide HVM efficiency. During singulation, organic dielectric material (e.g., buildup film) will persist on the sidewalls of the glass cores as an indication that such a reconstituted panel process was used.

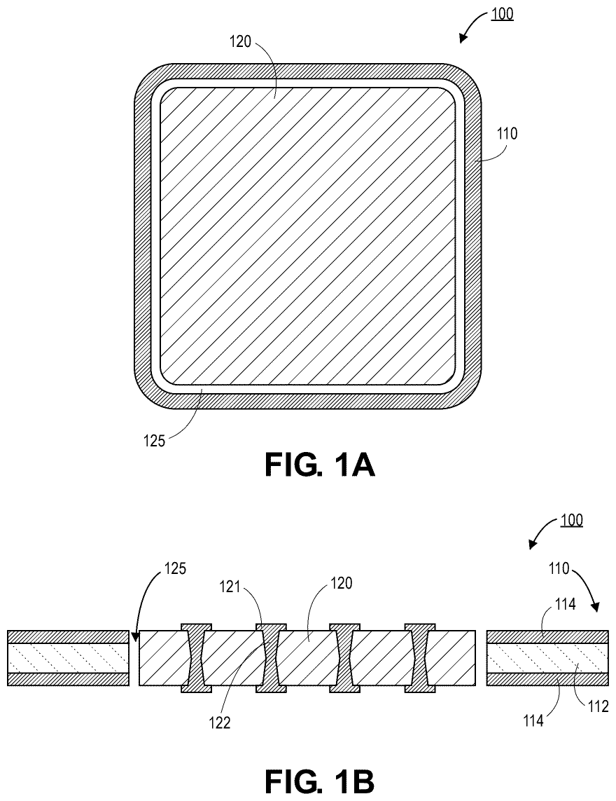

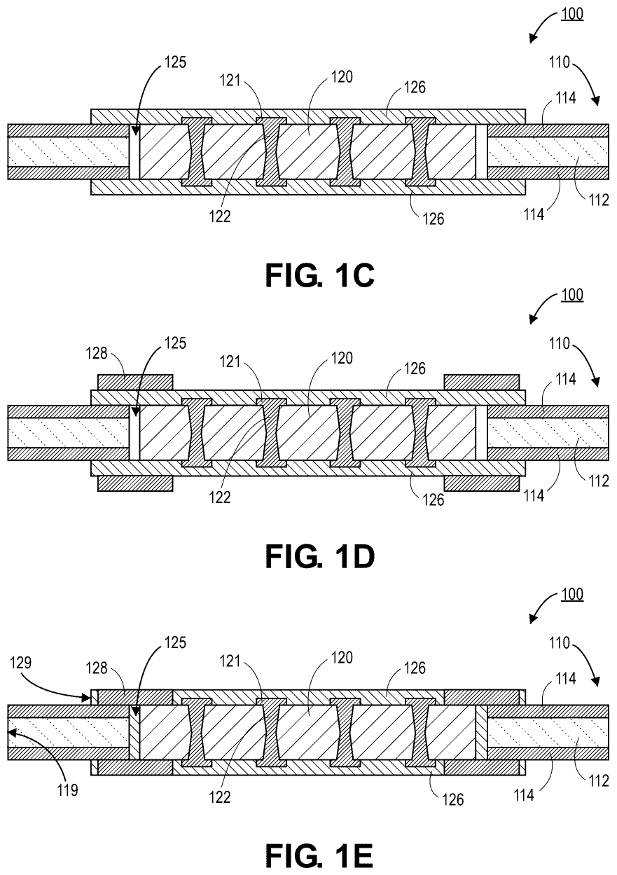

Referring now to FIG. 1A, a plan view illustration of a hybrid panel 100 is shown, in accordance with an embodiment. In an embodiment, the hybrid panel 100 may comprise a glass substrate 120. The glass substrate 120 may be surrounded by a frame 110. In an embodiment, the frame 110 may comprise an organic dielectric material, such as an organic polymer with glass fiber reinforcement material. In an embodiment, a gap 125 is provided between an outer edge of the glass substrate 120 and an inner edge of the frame 110.

In one embodiment, the hybrid panel 100 may have a form factor that is substantially equal to standard panel form factors or quarter panel form factors for semiconductor packaging applications. That is, the outer edge of the frame 110 has an outer perimeter that is substantially equal to that of standard form factors. Accordingly, the glass substrate 120 may have a slightly smaller panel (SSP) form factor in order to fit within the frame 110.

In an embodiment, the glass substrate 120 may be substantially all glass. The glass substrate 120 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass substrate 120 may be distinguished from, for example, the “prepreg” or “FR4” core of a Printed Circuit Board (PCB) substrate which typically comprises glass fibers embedded in a resinous organic material, such as an epoxy.

The glass substrate 120 may have any suitable dimensions. In a particular embodiment, the glass substrate 120 may have a thickness that is approximately 50 μm or greater. For example, the thickness of the glass substrate 120 may be between approximately 50 μm and approximately 1.4 mm. Though, smaller or larger thicknesses may also be used. Individual units (after singulation) from the glass substrate 120 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the individual units in the glass substrate 120 (from an overhead plan view) may be between approximately 10 mm×10 mm and approximately 250 mm×250 mm. In an embodiment, the glass substrate 120 may have a first side that is perpendicular or orthogonal to a second side. In a more general embodiment, the glass substrate 120 may comprise a rectangular prism volume with sections (e.g., vias) removed and filled with other materials (e.g., metal, etc.).

The glass substrate 120 may comprise a single monolithic layer of glass. In other embodiments, the glass substrate 120 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass substrate 120 may each have a thickness less than approximately 50 μm. For example, discrete layers of glass in the glass substrate 120 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass substrate 120 may be any suitable glass formulation that has the necessary mechanical robustness and compatibility with semiconductor packaging manufacturing and assembly processes. For example, the glass substrate 120 may comprise aluminosilicate glass, borosilicate glass, alumino-borosilicate glass, silica, fused silica, or the like. In some embodiments, the glass substrate 120 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass substrate 120 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass substrate 120 may comprise at least 23 percent silicon (by weight) and at least 26 percent oxygen (by weight). In some embodiments, the glass substrate 120 may further comprise at least 5 percent aluminum (by weight).

In the hybrid panel 100 shown in FIG. 1A, the glass substrate 120 is not directly coupled to the frame 110. However, as will be described in greater detail below, the glass substrate 120 may be secured to the frame by a fill material. The fill material may at least partially fill the gaps 125 between the frame 110 and the glass substrate 120. Additionally, reinforcement strips may be provided across the gaps 125 to further reduce the stress at the joint. As such, the durability and/or reliability of the hybrid panel 100 is increased.

Referring now to FIGS. 1B-1E, a series of cross-sectional illustrations depicting a process for forming a hybrid panel 100 with a glass substrate 120 and an organic frame 110 is shown, in accordance with an embodiment.

Referring now to FIG. 1B, a cross-sectional illustration of the hybrid panel 100 at a state of manufacture is shown, in accordance with an embodiment. In an embodiment, the hybrid panel 100 may be similar to the hybrid panel 100 described above with respect to FIG. 1A. For example, the hybrid panel 100 comprises a glass substrate 120, which may be similar to any of the glass substrates described in greater detail herein. The glass substrate 120 may be surrounded by a frame 110. The frame 110 may comprise an organic layer 112. The organic layer 112 may comprise an epoxy, a resin, or other polymeric material. The organic layer 112 may be reinforced with glass fibers, inorganic particles, and/or the like in some embodiments. In an embodiment, layers 114 may be provided over and/or under the organic layer 112. For example, the layers 114 may comprise copper or the like.

In an embodiment, the glass substrate 120 may comprise one or more vias 122 that pass through a thickness of the glass substrate 120. The vias 122 may have tapered sidewalls. For example, the sidewalls of the vias 122 in FIG. 1B provide an hourglass-shaped profile. Such a profile may be generated through the use of laser assisted patterning processes. Though, the vias 122 may have any suitable profile. Pads 121 may be provided over and/or under the vias 122. The glass substrate 120 may have a SSP form factor. Accordingly, the glass substrate 120 may accommodate a plurality of devices (not individually shown) that are all within the same glass substrate 120.

In an embodiment, the outer edge of the glass substrate 120 may be spaced apart from an inner edge of the frame 110 by a gap 125. The gap 125 may be up to approximately 50 μm, up to approximately 100 μm, or up to approximately 500 μm. Though, larger gaps 125 may also be used in some embodiments. For example, gaps 125 up to approximately 10 mm may also be used in some embodiments.

In an embodiment, the glass substrate 120 may be aligned within the frame 110 with any suitable alignment process. For example, alignment may be provided by a fiducial based pneumatic driven position system, a guide pin system, a roller-based self-alignment, a mechanical pushing system, an adjustable base table system, or the like. In an embodiment, the relative position of the frame 110 and the glass substrate 120 may be fixed after alignment.

Referring now to FIG. 1C, a cross-sectional illustration of the hybrid panel 100 after buildup layers 126 are provided over the top surface and the bottom surface of the glass substrate 120 is shown, in accordance with an embodiment. The buildup layers 126 may comprise an organic material, such as a buildup film or the like. The buildup layers 126 may be laminated over the glass substrate 120. For example, a roll laminator may be used, or an auto cutter followed by a rubber press may be used. In an embodiment, the buildup layers 126 may also cover at least a portion of the frame 110. That is, the buildup layers 126 may extend across the gap 125. As shown, the buildup layers 126 may not be as wide as the frame 110. Accordingly, there may be space for manufacturing equipment to secure the hybrid panel 100. For example, molding processes or the like may clamp an edge of the hybrid panel 100 in some operations.

Referring now to FIG. 1D, a cross-sectional illustration of the hybrid panel 100 after reinforcement strips 128 are applied over the buildup layers 126 is shown, in accordance with an embodiment. In an embodiment, the reinforcement strips 128 may comprise a material with a high strength surface layer. For example, the reinforcement strips 128 may comprise glass cloth prepreg, resin coated copper (RCC), or any other resin bonded with a high strength surface layer. In an embodiment, the reinforcement strips 128 may be applied around a perimeter of the glass substrate 120. For example, four reinforcement strips 128 are shown in FIG. 1D (e.g., two reinforcement strips 128 on the top surface and two reinforcement strips 128 on the bottom surface).

While a plurality of discrete reinforcement strips 128 are shown in FIG. 1D, it is to be appreciated that a single reinforcement strip 128 may be provided on each surface. For example, the reinforcement strips 128 may be a continuous ring that extends around the outer perimeter of the glass substrate 120. As shown, the reinforcement strips 128 have a width that allows the reinforcement strips 128 to be positioned above both the frame 110 and the glass substrate 120. That is, the reinforcement strips 128 extend across (or span) the gap 125 between the frame 110 and the glass substrate 120.

Referring now to FIG. 1E, a cross-sectional illustration of the hybrid panel 100 after a compression molding process is shown, in accordance with an embodiment. As shown, the compression molding forces the reinforcement strips 128 towards the surfaces of the glass substrate 120 and the frame 110. The reinforcement strips 128 may be at least partially embedded within the buildup layers 126. Additionally, the compression molding process may result in the buildup layers 126 at least partially filling the gap 125 between the frame 110 and the glass substrate 120. As shown in FIG. 1E, an edge 129 of the buildup layers 126 is set back from an edge 119 of the frame 110. This allows for space to clamp the frame 110 during one or more processing operations.

Accordingly, the hybrid panel 100 is formed with the glass substrate 120 securely coupled to the frame 110. Further, the reinforcement strips 128 increase the mechanical reliability of the joint across the gap 125. For example, the presence of the reinforcement strips 128 can reduce interface stress by up to approximately 40% or more, depending on the material composition of the reinforcement strips 128, the placement locations, etc.

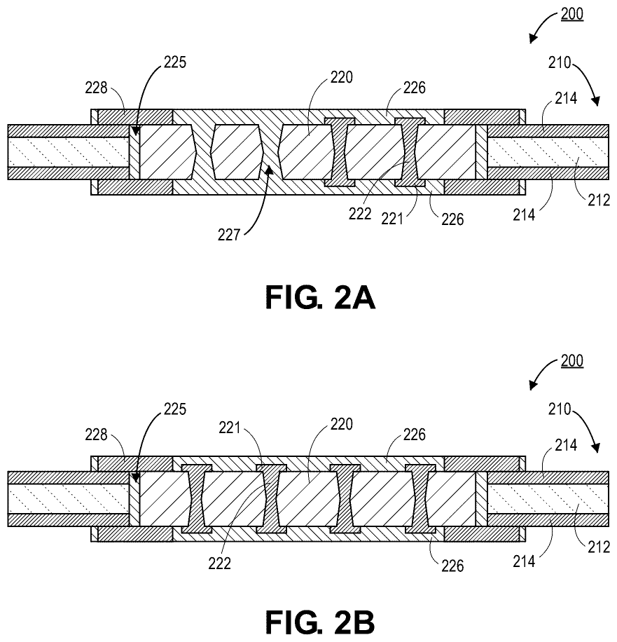

Referring now to FIGS. 2A and 2B, a pair of cross-sectional illustrations depicting alternative constructions of a hybrid panel 200 are shown, in accordance with additional embodiments.

Referring now to FIG. 2A, a cross-sectional illustration of a hybrid panel 200 is shown, in accordance with an embodiment. The hybrid panel 200 in FIG. 2A may be similar to the hybrid panel 100 in FIG. 1E, with the exception of the glass substrate 220. For example, the hybrid panel 200 may comprise a frame 210 (with an organic layer 212 and layers 214) that is bonded to the glass substrate 220 by buildup layers 226. Reinforcement strips 228 may also be provided across the gaps 225 between the frame 210 and the glass substrate 220.

However, in addition to the vias 222 and pads 221 on the glass substrate 220, cavities 227 may be provided through the glass substrate 220. The cavities 227 may be filled with the buildup layers 226 during the compression molding process used to compress the reinforcement strips 228 against the glass substrate 220. The cavities 227 may be used for any suitable purpose. In some embodiments, the cavities 227 may provide a location for embedding one or more components (e.g., passive components, active components, etc.) within the glass substrate 220.

Referring now to FIG. 2B, a cross-sectional illustration of a hybrid panel 200 is shown, in accordance with an additional embodiment. In an embodiment, the hybrid panel 200 in FIG. 2B is similar to the hybrid panel 100 in FIG. 1E, with the exception of the material used for the reinforcement strips 228. For example, the reinforcement strips 228 in FIG. 2B may be a fully metallic material, such as copper strips. The use of higher strength material for the reinforcement strips 228 may further improve the stress reduction across the joint over the gaps 225.

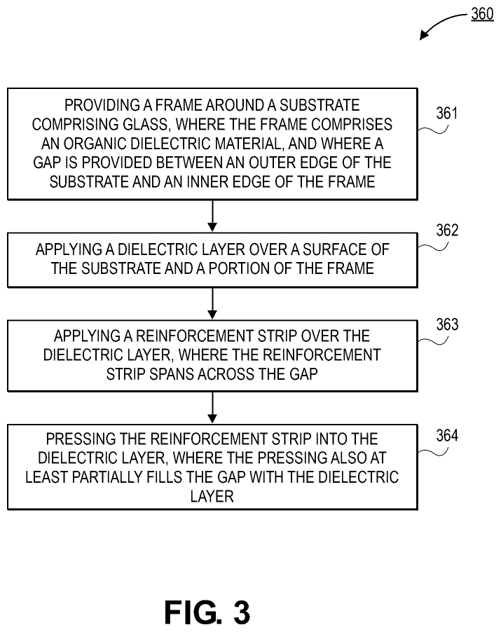

Referring now to FIG. 3, a flow diagram of a process 360 for forming a hybrid panel is shown, in accordance with an embodiment. The hybrid panel fabricated with process 360 may be similar to the hybrid panels described in greater detail with respect to FIGS. 1A-1E and/or FIGS. 2A-2B. In an embodiment, the process 360 may begin with operation 361, which comprises providing a frame around a substrate comprising glass. In an embodiment, the frame comprises an organic dielectric material. A gap may be provided between an outer edge of the substrate and an inner edge of the frame.

In an embodiment, the process 360 may continue with operation 362, which comprises applying a dielectric layer over a surface of the substrate and a portion of the frame. The dielectric layer may span the gap between the substrate and the frame. In an embodiment, the dielectric layer may be a buildup film, or the like. In some instances, the dielectric layer may be referred to as a buffer layer. The dielectric layer may be applied with a lamination process or the like.

In an embodiment, the process 360 may continue with operation 363, which comprises applying a reinforcement strip over the dielectric layer. The reinforcement strip may span across the gap between the frame and the substrate. In an embodiment, the reinforcement strip may comprise any material with a high strength surface layer. For example, the reinforcement strip may comprise a glass cloth prepreg, an RCC, or any other resin bonded with a high strength surface layer.

In an embodiment, the process 360 may continue with operation 364, which comprises pressing the reinforcement strip into the dielectric layer. In an embodiment, the reinforcement strip is pressed down until it contacts the frame and/or the substrate. The pressing may also result in the dielectric layer at least partially filling the gap between the frame and the substrate. The pressing process may be part of a compression molding process or the like.

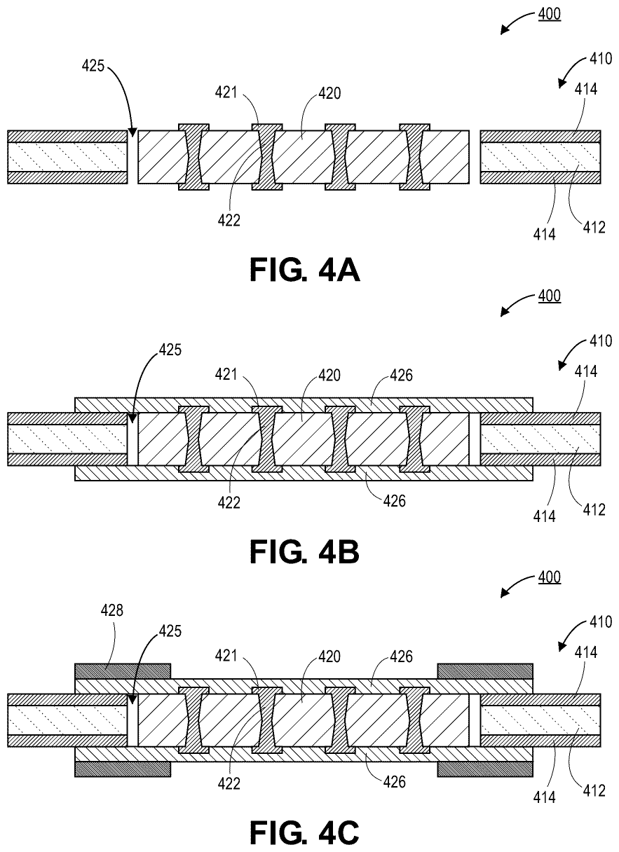

Referring now to FIGS. 4A-4F, a series of cross-sectional illustrations depicting a process for forming a hybrid panel 400 with a glass substrate 420 and an organic frame 410 is shown, in accordance with an embodiment.

Referring now to FIG. 4A, a cross-sectional illustration of the hybrid panel 400 at a state of manufacture is shown, in accordance with an embodiment. In an embodiment, the hybrid panel 400 may be similar to the hybrid panel 100 described above with respect to FIG. 1B. For example, the hybrid panel 400 comprises a glass substrate 420 that may be similar to any of the glass substrates described in greater detail herein. The glass substrate 420 may be surrounded by a frame 410. The frame 410 may comprise an organic layer 412. The organic layer 412 may comprise an epoxy, a resin, or other polymeric material. The organic layer 412 may be reinforced with glass fibers, inorganic particles, and/or the like in some embodiments. In an embodiment, layers 414 may be provided over and/or under the organic layer 412. For example, the layers 414 may comprise copper or the like. In an embodiment, the outer edge of the frame 410 may be larger than a standard panel size (or quarter panel size). The larger form factor allows for trimming in a subsequent processing operation.

In an embodiment, the glass substrate 420 may comprise one or more vias 422 that pass through a thickness of the glass substrate 420. The vias 422 may have tapered sidewalls or any other suitable profile. Pads 421 may be provided over and/or under the vias 422. The glass substrate 420 may have a SSP form factor. Accordingly, the glass substrate 420 may accommodate a plurality of devices (not individually shown) that are all within the same glass substrate 420.

In an embodiment, the outer edge of the glass substrate 420 may be spaced apart from an inner edge of the frame 410 by a gap 425. The gap 425 may be up to approximately 50 μm, up to approximately 100 μm, or up to approximately 500 μm. Though, larger gaps 425 may also be used in some embodiments. For example, gaps 425 up to approximately 10 mm may also be used in some embodiments.

Referring now to FIG. 4B, a cross-sectional illustration of the hybrid panel 400 after buildup layers 426 are provided over the top surface and the bottom surface of the glass substrate 420 is shown, in accordance with an embodiment. The buildup layers 426 may comprise an organic material, such as a buildup film or the like. The buildup layers 426 may be laminated over the glass substrate 420 with any suitable process, such as those described in greater detail herein. In an embodiment, the buildup layers 426 may also cover at least a portion of the frame 410. That is, the buildup layers 426 may extend across the gap 425. As shown, the buildup layers 426 may not be as wide as the frame 410. Accordingly, there may be space for manufacturing equipment to secure the hybrid panel 400. For example, molding processes or the like may clamp an edge of the hybrid panel 400 in some operations.

Referring now to FIG. 4C, a cross-sectional illustration of the hybrid panel 400 after reinforcement strips 428 are applied over the buildup layers 426 is shown, in accordance with an embodiment. In an embodiment, the reinforcement strips 428 may comprise a material with a high strength surface layer, such as any of the reinforcement strip 428 materials described in greater detail herein. In an embodiment, the reinforcement strips 428 may be applied around a perimeter of the glass substrate 420. For example, four reinforcement strips 428 are shown in FIG. 4C (e.g., two reinforcement strips 428 on the top surface and two reinforcement strips 428 on the bottom surface).

While a plurality of discrete reinforcement strips 428 are shown in FIG. 4C, it is to be appreciated that a single reinforcement strip 428 may be provided on each surface. For example, the reinforcement strips 428 may be a continuous ring that extends around the outer perimeter of the glass substrate 420. As shown, the reinforcement strips 428 have a width that allows the reinforcement strips 428 to be positioned above both the frame 410 and the glass substrate 420. That is, the reinforcement strips 428 extend across (or span) the gap 425 between the frame 410 and the glass substrate 420.

Referring now to FIG. 4D, a cross-sectional illustration of the hybrid panel 400 after a compression molding process is shown, in accordance with an embodiment. As shown, the compression molding forces the reinforcement strips 428 towards the surfaces of the glass substrate 420 and the frame 410. The reinforcement strips 428 may be at least partially embedded within the buildup layers 426. Additionally, the compression molding process may result in the buildup layers 426 at least partially filling the gap 425 between the frame 410 and the glass substrate 420.

Referring now to FIG. 4E, a cross-sectional illustration of the hybrid panel 400 with trim lines 411 highlighted is shown, in accordance with an embodiment. As shown, the trim lines 411 pass through the frame 410 and the reinforcement strips 428. In an embodiment, the hybrid panel 400 is trimmed along the trim line 411 to produce the hybrid panel 400 shown in FIG. 4F. As shown, the outer edge 419 of the frame 410 is substantially coplanar with an outer edge 429 of the reinforcement strip 428 due to a single trimming process being used to remove the outer edges of the frame 410 (and a portion of the reinforcement strips 428). The trimmed hybrid panel 400 may have a form factor of a standard panel form factor or a standard quarter panel form factor. The trimming process allows for the creation of a flush surface, which may be beneficial for subsequent processing. Additionally, the trimming allows for wider reinforcement strips without concern of bleed out, and the reinforcement strips can cover up to the entire remaining top and/or bottom surfaces of the frame 410. The higher surface coverage may provide improved stress reduction.

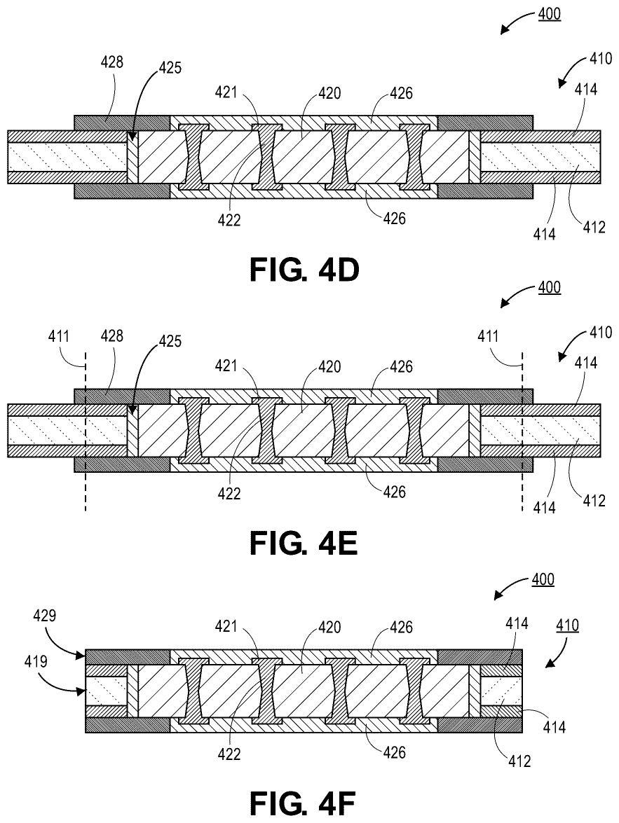

Referring now to FIG. 5, a flow diagram of a process 570 for forming a hybrid panel is shown, in accordance with an embodiment. The hybrid panel fabricated with process 570 may be similar to the hybrid panel 400 described in greater detail with respect to FIGS. 4A-4F. In an embodiment, the process 570 may begin with operation 571, which comprises providing a frame around a substrate comprising glass. In an embodiment, the frame comprises an organic dielectric material. A gap may be provided between an outer edge of the substrate and an inner edge of the frame.

In an embodiment, the process 570 may continue with operation 572, which comprises applying a dielectric layer over a surface of the substrate and a portion of the frame. The dielectric layer may span the gap between the substrate and the frame. In an embodiment, the dielectric layer may be a buildup film, or the like. In some instances, the dielectric layer may be referred to as a buffer layer. The dielectric layer may be applied with a lamination process or the like.

In an embodiment, the process 570 may continue with operation 573, which comprises applying a reinforcement strip over the dielectric layer. The reinforcement strip may span across the gap between the frame and the substrate. In an embodiment, the reinforcement strip may comprise any material with a high strength surface layer. For example, the reinforcement strip may comprise a glass cloth prepreg, an RCC, or any other resin bonded with a high strength surface layer.

In an embodiment, the process 570 may continue with operation 574, which comprises pressing the reinforcement strip into the dielectric layer. In an embodiment, the reinforcement strip is pressed down until it contacts the frame and/or the substrate. The pressing may also result in the dielectric layer at least partially filling the gap between the frame and the substrate. The pressing process may be part of a compression molding process or the like.

In an embodiment, the process 570 may continue with operation 575, which comprises trimming the reinforcement strip and the frame so an outer edge of the frame is substantially coplanar with an outer edge of the reinforcement strip. As used herein, “substantially coplanar” may refer to two surfaces that oriented at an angle up to 5° from each other. More generally, substantially coplanar surfaces may be formed when a single linear cut (e.g., mechanical, laser, plasma, etc.) is formed through two layers. In such an embodiment, the surfaces of the two layers exposed by the single linear cut would be substantially coplanar.

In the embodiments described above, hybrid panels that are used for full panel assemblies or quarter panel assemblies are shown. However, it is to be appreciated that other embodiments described herein may also include hybrid panels that are reconstituted panels. In a reconstituted panel embodiment, one or more glass substrate pieces are embedded in a dielectric layer that is surrounded by a frame (such as an organic frame). In such an embodiment, the geometry of the reconstituted panel can vary greatly in size, depending on need. For example, reconstituted panels from tens of millimeters per edge to hundreds of millimeters per edge may be enabled. The subsequent singulation of the reconstituted panel into units or smaller reconstituted portions may only need to cut through the dielectric material, rather than glass, which makes the cutting easier. Further the resulting units or smaller reconstituted portions will still retain dielectric material over the sidewalls of the glass in order to provide additional downstream protection to the glass core.

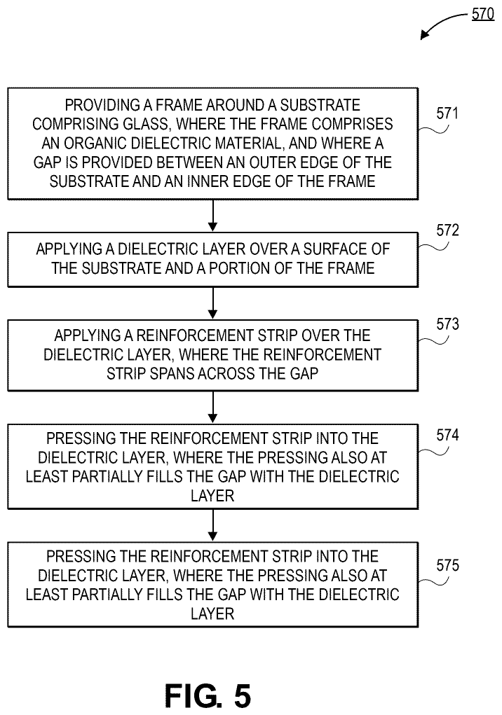

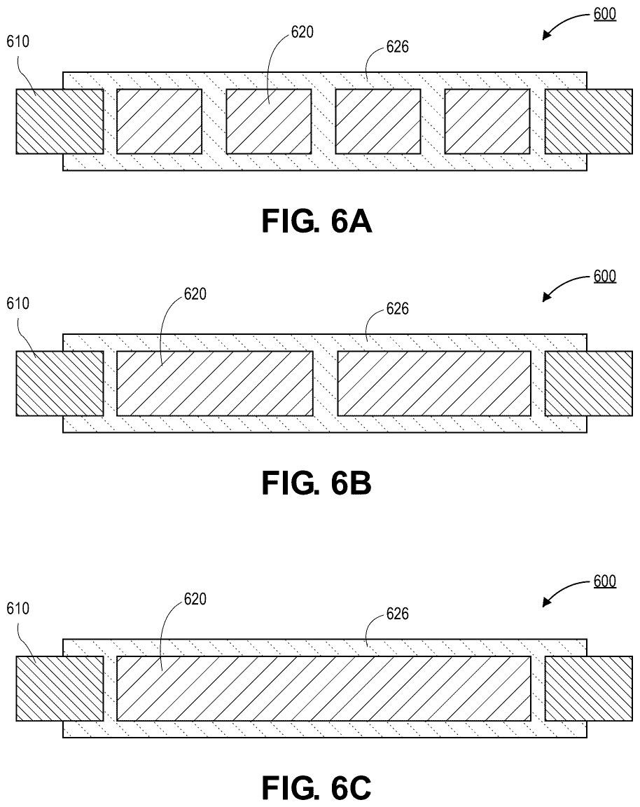

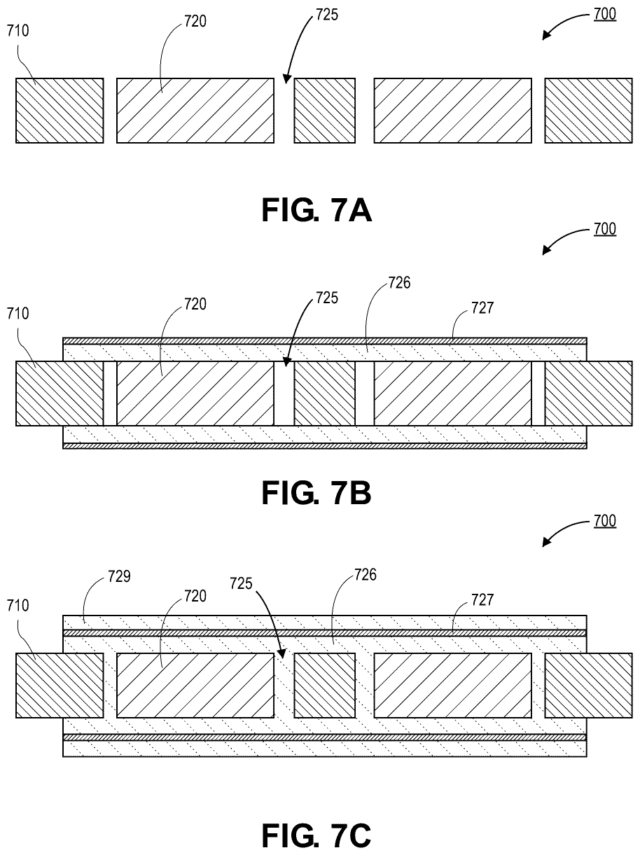

Referring now to FIGS. 6A-6C, a series of different reconstituted hybrid panels 600 are shown, in accordance with various embodiments.

In FIG. 6A, the reconstituted hybrid panel 600 comprises a frame 610 that surrounds a plurality of glass substrates 620. The glass substrates 620 may be embedded in a dielectric layer 626, such as a buildup film, an epoxy, a molding material, or the like. That is, the glass substrates 620 may be spaced apart from each other, and the dielectric layer 626 fills the gap between the glass substrates 620. In an embodiment, the frame 610 may comprise an organic dielectric material. The frame 610 may be similar to any of the frames described in greater detail herein. In FIG. 6A, the plurality of glass substrates 620 may each be an individual unit. That is, each of the glass substrates 620 may ultimately be singulated to be the core for different package substrates. The glass substrates 620 may be similar in material composition and/or structure as any of the glass substrates described in greater detail herein.

In FIG. 6B, a reconstituted hybrid panel 600 with a quarter panel design is shown. As shown, the glass substrates 620 may each comprise a quarter panel form factor. In the case of a quarter panel glass substrate 620, the quarter panel may ultimately be singulated into smaller units. In FIG. 6C, the reconstituted hybrid panel 600 includes a single panel form factor glass substrate 620. Such a reconstituted hybrid panel 600 may have a glass substrate 620 that has a SSP form factor in order to accommodate the frame 610.

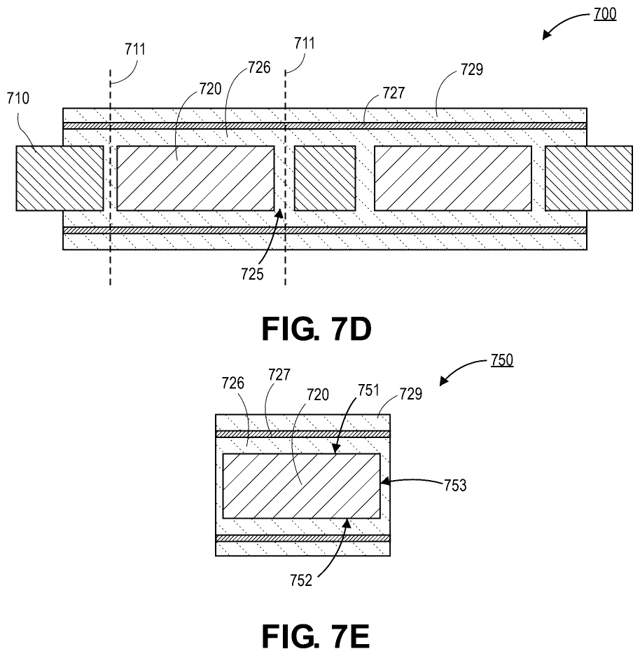

Referring now to FIGS. 7A-7E, a series of cross-sectional illustrations depicting a process for forming a unit 750 from a reconstituted hybrid panel 700 is shown, in accordance with an embodiment.

Referring now to FIG. 7A, a cross-sectional illustration of a reconstituted hybrid panel 700 at a stage of manufacture is shown, in accordance with an embodiment. As shown, a frame 710 may surround portions of glass substrates 720. Each of the glass substrates 720 may comprise a glass core for a single unit 750 that will be singulated from the reconstituted hybrid panel 700. In the illustrated embodiment, each of the glass substrates 720 are surrounded by the frame 710. Though, other embodiments may include glass substrates 720 that are adjacent to each other without a portion of the frame 710 in between (e.g. similar to the embodiment shown in FIG. 6A). In an embodiment, sidewalls of the glass substrates 720 may be spaced apart from the sidewalls of the frame 710 be a gap 725. The glass substrates 720 may be similar to any of the glass substrates described in greater detail herein, and the frame 710 may be similar to any of the frames described in greater detail herein.

Referring now to FIG. 7B, a cross-sectional illustration of the reconstituted hybrid panel 700 after a reconstitution layer is applied on the top surface and the bottom surface of the frame 710 and the glass substrates 720. In the illustrated embodiment, the reconstitution layer comprises a dielectric layer 726 and a metallic layer 727 over the dielectric layer 726. For example, the reconstitution layer may comprise an RCC layer. Though, any suitable molding material, epoxy, or the like can be used for the reconstitution layer.

Referring now to FIG. 7C, a cross-sectional illustration of the reconstituted hybrid panel 700 after a pressing process and a buildup layer 729 lamination is implemented is shown, in accordance with an embodiment. The pressing process may include a molding process or the like. During the pressing process, the dielectric layer 726 is pressed into the gaps 725. The buildup layer 729 may be applied with a lamination process or the like. In the illustrated embodiment, the dielectric layer 726 and the buildup layer 729 are shown with the same shading. Though, in other embodiments, the dielectric layer 726 and the buildup layer 729 may include different materials. After the pressing process, any number of buildup layers 729 (and associated electrical routing) may be provided on and/or under the reconstituted hybrid panel 700. That is, each package unit may be fabricated at the panel level to improve HVM efficiencies.

Referring now to FIG. 7D, a cross-sectional illustration of the reconstituted hybrid panel 700 with cut lines 711 illustrated is shown, in accordance with an embodiment. In an embodiment, the cut lines 711 are provided adjacent to the glass substrates 720. More particularly, the cut lines 711 pass through the gaps 725. Accordingly, the subsequent cutting process (e.g., mechanical, laser, plasma, etc.) does not need to pass through any glass.

Referring now to FIG. 7E, a cross-sectional illustration of a unit 750 that is singulated from the reconstituted hybrid panel 700 is shown, in accordance with an embodiment. As shown, the glass substrate 720 comprises a first surface 751, a second surface 752, and a sidewall surface 753. Additionally, all of the surfaces 751-753 are covered by the dielectric layer 726. Accordingly, the glass substrate 720 (which may be referred to as a glass core) is protected along all surfaces during any further downstream processing.

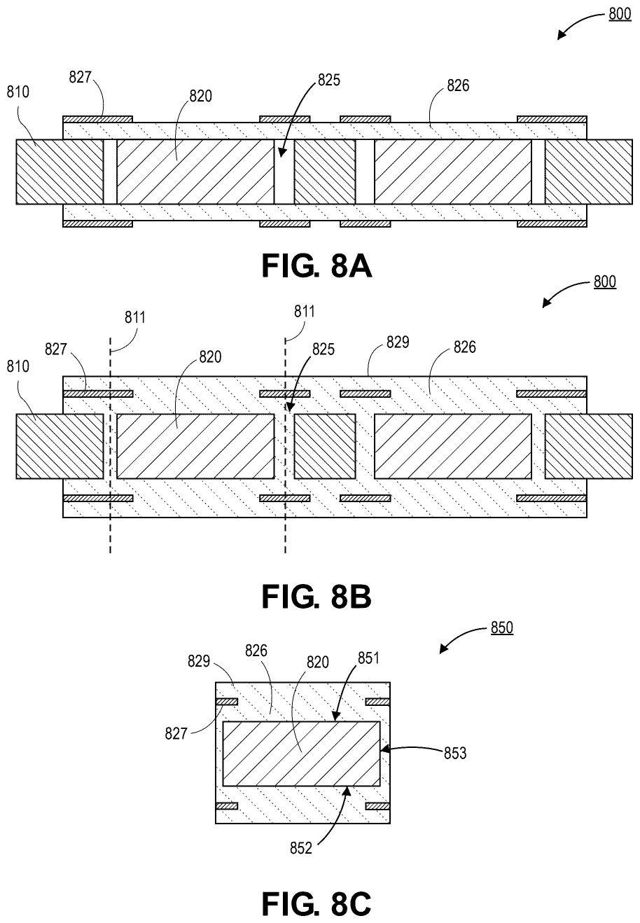

Referring now to FIGS. 8A-8C, a series of cross-sectional illustrations depicting an alternative process for forming a singulated unit 850 from a reconstituted hybrid panel 800 is shown, in accordance with an embodiment.

Referring now to FIG. 8A, a cross-sectional illustration of the reconstituted hybrid panel 800 with the reconstitution layers applied over the frame 810 and the glass substrates 820 is shown, in accordance with an embodiment. The reconstitution layers may comprise a dielectric layer 826 and a metal layer 827. However, instead of leaving a blanket metal layer 827 across the dielectric layer 826, portions of the metal layer 827 have been removed with an etching process. The removal of portions of the metal layer 827 allows for easier electrical access to vias (not shown) that may be formed through the glass substrates 820. In the illustrated embodiment, the metal layer 827 patterning is done before the dielectric layer 826 is pressed into the gaps 825. Though, in other embodiments, the dielectric layer 826 may be pressed into the gaps 825 before the metal layer 827 is patterned.

Referring now to FIG. 8B, a cross-sectional illustration of the reconstituted hybrid panel 800 after the pressing operation to fill the gaps 825 and a subsequent buildup layer 829 lamination is shown, in accordance with an embodiment. The cut lines 811 are also shown. Similar to the embodiment above, the cut lines 811 do not need to pass through any glass.

Referring now to FIG. 8C, a cross-sectional illustration of a unit 850 that is singulated from the reconstituted hybrid panel 800 is shown, in accordance with an embodiment. As shown, the glass substrate 820 comprises a first surface 851, a second surface 852, and a sidewall surface 853. Additionally, all of the surfaces 851-853 are covered by the dielectric layer 826. Accordingly, the glass substrate 820 (which may be referred to as a glass core) is protected along all surfaces during any further downstream processing. Additionally, the unit 850 may comprise residual portions of the metal layer 827. The residual portion of the metal layer 827 may have an edge surface that is substantially coplanar with an edge surface of the dielectric layer 826 due to the use of a single linear cut. The opposite edge of the residual portion of the metal layer 827 may be positioned within a footprint of the glass substrate 820. That is, the residual portion of the metal layer 827 does not extend across an entire width of the glass substrate 820 in some embodiments. In an embodiment, the residual portions of the metal layer 827 may be electrically floating. That is, the residual portions of the metal layer 827 may not be directly contacted by other electrically conductive features within the unit 850.

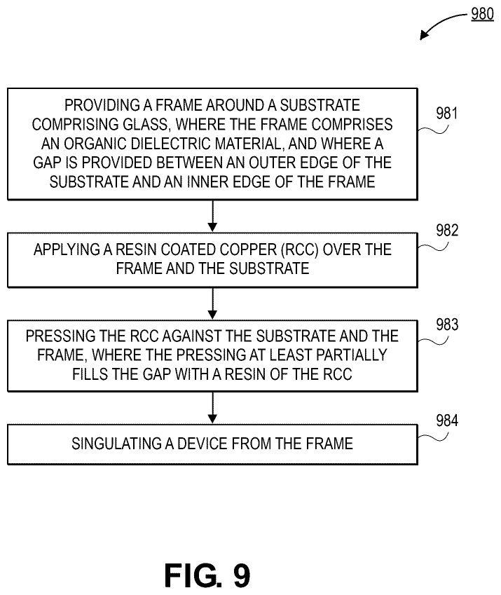

Referring now to FIG. 9, a flow diagram of a process 980 for forming a unit from a reconstituted hybrid panel is shown, in accordance with an embodiment. In an embodiment, the process 980 may begin with operation 981, which comprises providing a frame around a substrate comprising glass. In an embodiment, the frame comprises an organic dielectric material, similar to any of the frames described in greater detail herein. The substrate may be similar to any of the glass substrates described in greater detail herein. In an embodiment, a gap is provided between an outer edge of the substrate and an inner edge of the frame.

In an embodiment, the process 980 may continue with operation 982, which comprises applying an RCC (or other dielectric material) over the frame and the substrate. In an embodiment, the RCC may be applied with a lamination process or the like.

In an embodiment, the process 980 may continue with operation 983, which comprises pressing the RCC against the substrate and the frame. In an embodiment, the pressing process at least partially fills the gap with a resin of the RCC. In an embodiment, the pressing process may be part of a molding process or the like.

In an embodiment, the process 980 may continue with operation 984, which comprises singulating a device comprising the substrate from the frame. In an embodiment, a portion of the resin of the RCC is retained along a top surface, a bottom surface, and sidewall surfaces of the substrate. The device may be similar to the device units 750 or 850 described in greater detail herein.

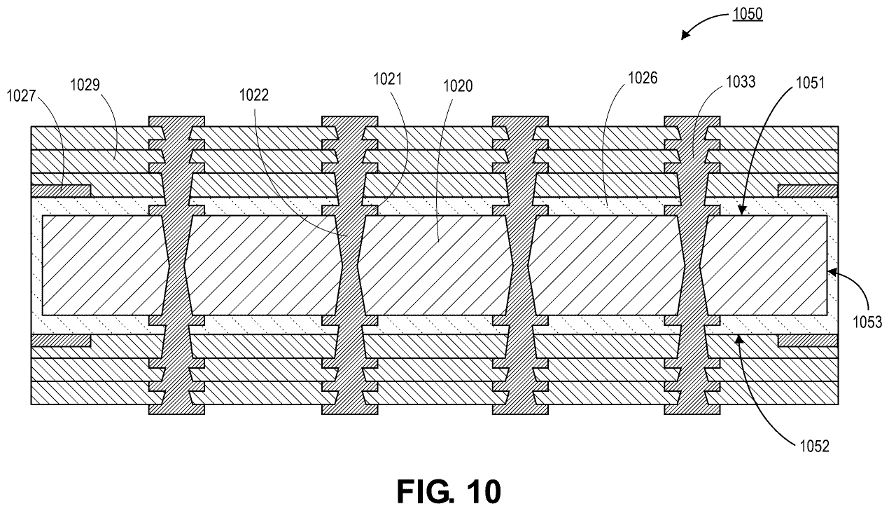

Referring now to FIG. 10, a cross-sectional illustration of a device 1050 is shown, in accordance with an embodiment. In an embodiment, the device 1050 may be formed from a reconstituted hybrid frame using a process similar to the process 980 described in greater detail herein. In an embodiment, the device 1050 may sometimes be referred to as a package substrate, an interposer, or the like. In an embodiment, the device 1050 may comprise a core 1020. In an embodiment, the core 1020 comprises a glass layer. The glass layer of the core 1020 may be similar to any of the glass layers or glass substrates described in greater detail herein. In some embodiments, vias 1022 may pass through a thickness of the core 1020, and pads 1021 may be provided over and/or under the vias 1022.

In an embodiment, a dielectric layer 1026 may be provided around a perimeter of the core 1020. The dielectric layer 1026 may be a buildup material, an epoxy, a molding material, or the like. The dielectric layer 1026 may form a ring around a perimeter of the core 1020. For example, the dielectric layer 1026 may directly contact a top surface 1051, a bottom surface 1052, and sidewall surfaces 1053 of the core 1020.

In an embodiment, residual portions of a metal layer 1027 may be provided over and/or under the dielectric layer 1026. The residual portions of the metal layer 1027 may extend to the edge of the dielectric layer 1026. The residual portions of the metal layer 1027 may also extend within a footprint of the core 1020. The residual portions of the metal layer 1027 may be electrically floating. That is, the residual portions of the metal layer 1027 may not be directly contacted by other electrical circuitry within the device 1050.

In an embodiment, the device 1050 may also comprise one or more buildup layers 1029 over and/or under the dielectric layer 1026. Electrical routing 1033 (e.g., pads, vias, traces, etc.) may be embedded in and/or provided on the one or more buildup layers 1029. In some embodiments, the dielectric layer 1026 is a different material than the one or more buildup layers 1029. Though, in other embodiments, the dielectric layer 1026 is the same material as the one or more buildup layers 1029. When the dielectric layer 1026 and the buildup layers 1029 are the same material, the presence of the residual portions of the metal layer 1027 may be used as one indication that a separate buffer layer (i.e., dielectric layer 1026) is provided over and/or under the core 1020.

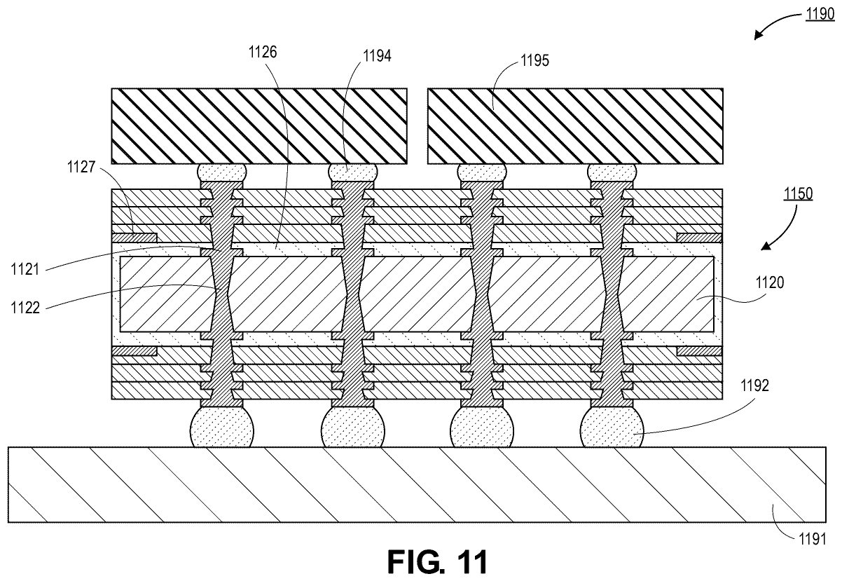

Referring now to FIG. 11, a cross-sectional illustration of an electronic system 1190 is shown, in accordance with an embodiment. In an embodiment, the electronic system 1190 may comprise a board 1191, such as a printed circuit board (PCB) a mother board, or the like. In an embodiment, the board 1191 may be coupled to a package substrate 1150 by interconnects 1192. The interconnects 1192 may be any suitable second level interconnect (SLI), such as solder balls, sockets, pins, or the like.

In an embodiment, the package substrate 1150 may comprise a core 1120. The core 1120 may be a glass core that is similar to any of the glass substrates or glass layers described in greater detail herein. The glass core 1120 may comprise vias 1122 with pads 1121 over and/or under the vias 1122. In an embodiment, the glass core 1120 may be surrounded by a protective dielectric layer 1126. The dielectric layer 1126 may be provided on a top surface, a bottom surface, and a sidewall surface of the glass core 1120. In an embodiment, residual metal layers 1127 may be provided over and/or under the dielectric layer 1126. The residual metal layers 1127 may extend to an edge of the package substrate 1150. The residual metal layers 1127 may also extend within a footprint of the glass core 1120 in some embodiments. In an embodiment, buildup layers with electrical routing (e.g., pads, traces, vias, etc.) may be provided over and/or under the dielectric layer 1126.

In an embodiment, one or more dies 1195 are coupled to the package substrate 1150 by interconnects 1194. In an embodiment, the interconnects 1194 may include any suitable first level interconnect (FLI) architecture. For example, the interconnects 1194 may comprise solder balls, copper bumps, hybrid bonding, and/or the like. In an embodiment, the one or more dies 1195 may comprise any type of die, such as a processor (e.g., a central processing unit (CPU), a graphics processing unit (GPU), etc.), a communications die, a memory die, and/or the like.

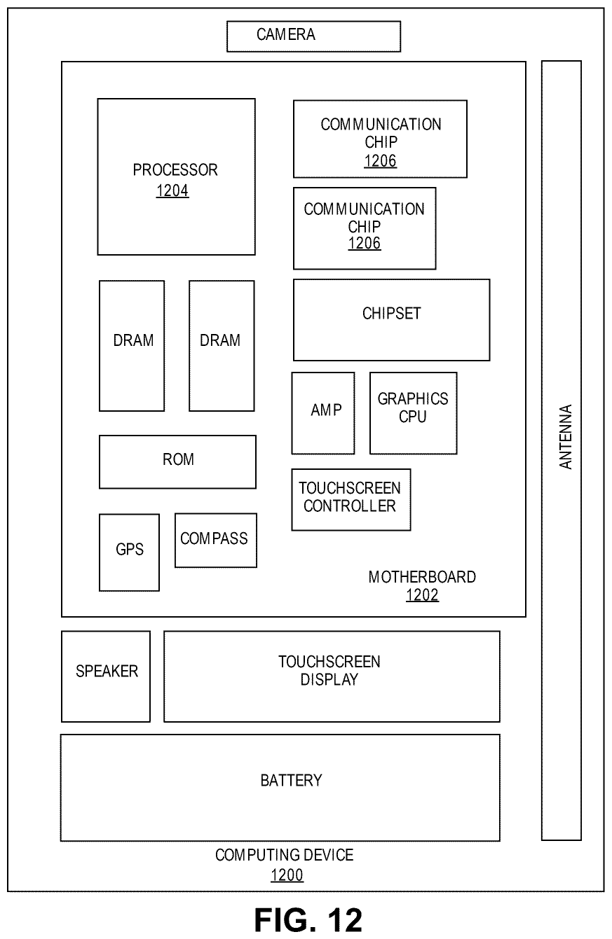

FIG. 12 illustrates a computing device 1200 in accordance with one implementation of the disclosure. The computing device 1200 houses a board 1202. The board 1202 may include a number of components, including but not limited to a processor 1204 and at least one communication chip 1206. The processor 1204 is physically and electrically coupled to the board 1202. In some implementations the at least one communication chip 1206 is also physically and electrically coupled to the board 1202. In further implementations, the communication chip 1206 is part of the processor 1204.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1206 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1206. For instance, a first communication chip 1206 may be dedicated to shorter range wireless communications such as Wi-Fi and Bluetooth and a second communication chip 1206 may be dedicated to longer range wireless communications such as GPS, EDGE, GPRS, CDMA, WiMAX, LTE, Ev-DO, and others.

The processor 1204 of the computing device 1200 includes an integrated circuit die packaged within the processor 1204. In some implementations of the disclosure, the integrated circuit die of the processor may be part of an electronic package that comprises a package substrate with a glass core that is embedded in a dielectric layer, in accordance with embodiments described herein. The term “processor” may refer to any device or portion of a device that processes electronic data from registers and/or memory to transform that electronic data into other electronic data that may be stored in registers and/or memory.

The communication chip 1206 also includes an integrated circuit die packaged within the communication chip 1206. In accordance with another implementation of the disclosure, the integrated circuit die of the communication chip may be part of an electronic package that comprises a package substrate with a glass core that is embedded in a dielectric layer, in accordance with embodiments described herein.

In an embodiment, the computing device 1200 may be part of any apparatus. For example, the computing device may be part of a personal computer, a server, a mobile device, a tablet, an automobile, or the like. That is, the computing device 1200 is not limited to being used for any particular type of system, and the computing device 1200 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example 1: an apparatus, comprising: a first layer with a first surface, a second surface, and a sidewall surface that couples the first surface to the second surface, wherein the first layer comprises a glass layer; a second layer on the first surface, the second surface, and the sidewall surface of the first layer, wherein the second layer is an organic dielectric material; and a third layer on the second layer, wherein the third layer is a metallic material, and wherein an edge of the third layer is substantially coplanar with an edge of the second layer.
Example 2: the apparatus of Example 1, wherein a second edge of the third layer opposite from the edge of the third layer that is substantially coplanar with the edge of the second layer is within a footprint of the first layer.
Example 3: the apparatus of Example 1 or Example 2, wherein the sidewall surface of the first layer is offset from the edge of the third layer.
Example 4: the apparatus of Examples 1-3, further comprising: a fourth layer on the second layer, wherein the third layer is over the first surface of the first layer and the fourth layer is below the second surface of the first layer, and wherein the fourth layer comprises the metallic material.
Example 5: the apparatus of Example 4, wherein an edge of the fourth layer is substantially coplanar with the edge of the second layer.
Example 6: the apparatus of Examples 1-5, wherein the third layer comprises copper.
Example 7: the apparatus of Examples 1-6, wherein the second layer comprises a resin.
Example 8: the apparatus of Examples 1-7, further comprising: a via through a thickness of the first layer.
Example 9: the apparatus of Examples 1-8, further comprising: one or more organic buildup layers over the second layer and the third layer.
Example 10: the apparatus of Example 9, further comprising: a die coupled to the one or more organic buildup layers; and a board coupled to the first layer.
Example 11: an apparatus, comprising: a substrate, wherein the substrate comprises a glass layer; a frame around the substrate, wherein the frame comprises a dielectric layer, and wherein a gap is provided between an outer edge of the substrate and an inner edge of the frame; a fill layer in the gap; and a reinforcement strip over the frame and the substrate, wherein the reinforcement strip is over the gap.
Example 12: the apparatus of Example 11, wherein the reinforcement strip comprises a glass cloth prepreg.
Example 13: the apparatus of Example 11 or Example 12, wherein the reinforcement strip comprises copper.
Example 14: the apparatus of Examples 11-13, wherein an edge of the reinforcement strip is set back from an outer edge of the frame.
Example 15: the apparatus of Examples 11-14, wherein an edge of the reinforcement strip is substantially coplanar with an outer edge of the frame.
Example 16: the apparatus of Examples 11-15, wherein the substrate is a panel level substrate, a quarter panel level substrate, or a unit level substrate.
Example 17: a hybrid panel, comprising: a substrate, wherein the substrate comprises a glass layer; a frame around a perimeter of the substrate, wherein the frame comprises a dielectric layer, and wherein a gap is provided between an inner edge of the frame and an outer edge of the substrate; a fill layer over and under the substrate and the frame, wherein the fill layer at least partially fills the gap; and a reinforcement strip that spans the gap, and wherein the reinforcement strip is over both the substrate and the frame.
Example 18: the hybrid panel of Example 17, wherein the reinforcement strip comprises a glass fiber prepreg or a copper layer.
Example 19: the hybrid panel of Example 17 or Example 18, wherein an outer portion of the frame is not covered by the fill layer.
Example 20: the hybrid panel of Examples 17-19, wherein an edge of the reinforcement strip is substantially coplanar with an outer edge of the frame.

What is claimed is:

1. An apparatus, comprising:
a first layer with a first surface, a second surface, and a sidewall surface that couples the first surface to the second surface, wherein the first layer comprises a glass layer;
a second layer on the first surface, the second surface, and the sidewall surface of the first layer, wherein the second layer is an organic dielectric material; and
a third layer on the second layer, wherein the third layer is a metallic material, and wherein an edge of the third layer is substantially coplanar with an edge of the second layer.

2. The apparatus of claim 1, wherein a second edge of the third layer opposite from the edge of the third layer that is substantially coplanar with the edge of the second layer is within a footprint of the first layer.

3. The apparatus of claim 1, wherein the sidewall surface of the first layer is offset from the edge of the third layer.

4. The apparatus of claim 1, further comprising:
a fourth layer on the second layer, wherein the third layer is over the first surface of the first layer and the fourth layer is below the second surface of the first layer, and wherein the fourth layer comprises the metallic material.

5. The apparatus of claim 4, wherein an edge of the fourth layer is substantially coplanar with the edge of the second layer.

6. The apparatus of claim 1, wherein the third layer comprises copper.

7. The apparatus of claim 1, wherein the second layer comprises a resin.

8. The apparatus of claim 1, further comprising:
a via through a thickness of the first layer.

9. The apparatus of claim 1, further comprising:
one or more organic buildup layers over the second layer and the third layer.

10. The apparatus of claim 9, further comprising:
a die coupled to the one or more organic buildup layers; and
a board coupled to the first layer.

11. An apparatus, comprising:
a substrate, wherein the substrate comprises a glass layer;
a frame around the substrate, wherein the frame comprises a dielectric layer, and wherein a gap is provided between an outer edge of the substrate and an inner edge of the frame;
a fill layer in the gap; and
a reinforcement strip over the frame and the substrate, wherein the reinforcement strip is over the gap.

12. The apparatus of claim 11, wherein the reinforcement strip comprises a glass cloth prepreg.

13. The apparatus of claim 11, wherein the reinforcement strip comprises copper.

14. The apparatus of claim 11, wherein an edge of the reinforcement strip is set back from an outer edge of the frame.

15. The apparatus of claim 11, wherein an edge of the reinforcement strip is substantially coplanar with an outer edge of the frame.

16. The apparatus of claim 11, wherein the substrate is a panel level substrate, a quarter panel level substrate, or a unit level substrate.

17. A hybrid panel, comprising:
a substrate, wherein the substrate comprises a glass layer;
a frame around a perimeter of the substrate, wherein the frame comprises a dielectric layer, and wherein a gap is provided between an inner edge of the frame and an outer edge of the substrate;
a fill layer over and under the substrate and the frame, wherein the fill layer at least partially fills the gap; and
a reinforcement strip that spans the gap, and wherein the reinforcement strip is over both the substrate and the frame.

18. The hybrid panel of claim 17, wherein the reinforcement strip comprises a glass fiber prepreg or a copper layer.

19. The hybrid panel of claim 17, wherein an outer portion of the frame is not covered by the fill layer.

20. The hybrid panel of claim 17, wherein an edge of the reinforcement strip is substantially coplanar with an outer edge of the frame.
